(19) United States
(12) Patent Application Publication
(10) Pub. No.: US 2017/0025625 A1
(43) Pub. Date: Jan. 26, 2017

(54) Metal Complex and Organic Light-Emitting Component

(71) Applicant: OSRAM GmbH, Muenchen (DE)

(72) Inventors: Jude Eko Namanga, Augsburg (DE); Niels Gerlitzki, Augsburg (DE)

(21) Appl. No.: 15/215,391

(22) Filed: Jul. 20, 2016

(30) Foreign Application Priority Data
Jul. 24, 2015 (DE) 10 2015 112 134.4

(51) Int. Cl. H01L 51/00; C07F 15/00; C09K 11/06

(52) U.S. Cl. CPC H01L 51/0085; C09K 11/06; C07F 15/0033; H01L 51/5012

(57) ABSTRACT

A metal complex and an organic light-emitting component are disclosed. In an embodiment, the metal complex includes the following structural formula I:

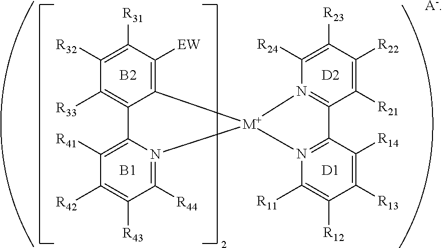

This patent application claims the priority of German patent application 10 2015 112 134.4, filed Jul. 24, 2015, which is incorporated herein by reference in its entirety.

### TECHNICAL FIELD

The invention relates to a metal complex. The invention further relates to an organic light-emitting component.

### BACKGROUND

Organic light-emitting components, especially organic light-emitting electrochemical cells (OLECs or LECs), include metal complexes, especially ionic transition metal complexes (iTMCs), as emitter materials, which can emit preferentially in the blue, sky blue, green, yellow-green, yellow, orange or red spectral region. However, these emitter materials are of low structural stability during the operation of the organic light-emitting component, and so the organic light-emitting component has a short lifetime.

### SUMMARY OF THE INVENTION

Embodiments of the invention provide a structurally stable metal complex. More particularly, the metal complex is structurally stable to degradation and/or at high temperatures and/or over a long period. Further embodiments of the invention provide a stable organic light-emitting component. More particularly, the component has a long lifetime with equal or high luminescence compared to components known to date that comprise conventional metal complexes.

In at least one embodiment, the metal complex has the structural formula I:

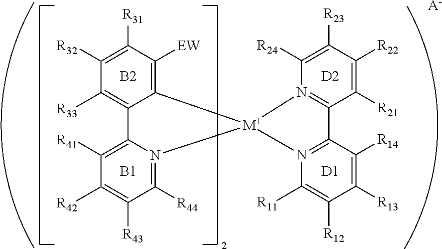

where:

M is a transition metal having an atomic number greater than 40,

the B2 ring is at least one aromatic or heteroaromatic,

the B1 ring, the D1 ring and the D2 ring are each at least one nitrogen-containing ring,

A⁻ is a monovalent anion,

EW is at least one electron-withdrawing substituent, R₁₁, R₁₂, R₁₃, R₁₄, R₂₁, R₂₂, R₂₃, R₂₄, R₄₁, R₄₂, R₄₃, R₄₄ are each independently selected from a group comprising —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀, R₃₁, R₃₂, R₃₃ are each independently a further electron-withdrawing substituent or are each independently selected from a group comprising —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀,

where R₅₀, R₆₀, R₇₀, R₈₀, R₉₀, R₁₀₀, R₁₁₀, R₂₀₀, R₂₁₀, R₂₂₀, R₂₃₀ are each independently selected from a group comprising unbranched saturated hydrocarbon chains having one to 20 carbon atoms, branched saturated hydrocarbon chains having one to 20 carbon atoms, unbranched unsaturated hydrocarbon chains having one to 20 carbon atoms, branched unsaturated hydrocarbon chains having one to 20 carbon atoms, aromatic rings, nonaromatic rings, —H, —I, —Cl, —Br, —F, N+R₁₂₀R₁₃₀R₁₄₀, —SO₃R₁₅₀, —CN, —COCl, —COOR₁₆₀, —CR₁₇₀R₁₈₀OH, —CR₁₉₀O and —CHO,

where R₁₂₀, R₁₃₀, R₁₄₀, R₁₅₀, R₁₆₀, R₁₇₀, R₁₈₀, R₁₉₀ are each independently selected from a group comprising unbranched saturated hydrocarbon chains having one to 20 carbon atoms, branched saturated hydrocarbon chains having one to 20 carbon atoms and cyclic rings having 3 to 20 carbon atoms.

“Metal complex” or metal complex compound here and hereinafter is understood to mean a chemical compound having a central atom of a transition metal M which has gaps in its electron configuration and is surrounded by at least one or more than one molecule or ion, also called ligands. The central atom may bear a positive charge (M⁺). The ligands each provide at least one free electron pair for the formation of the metal complex. The metal complex especially forms six coordinate bonds to the ligands. The ligands may be monodentate or bidentate. More particularly, bonds are formed from the central atom M to the B1, B2, D1 and D2 rings. Since the B1 and B2 rings are present twice in the metal complex, represented by the index 2 in the structural formula I, the result is six bonds from the respective rings to the central atom M. More particularly, the B1, D1 and D2 rings each coordinate via the nitrogen of the corresponding ring to M. More particularly, the B2 ring coordinates via a carbon in the B2 ring to M.

In at least one embodiment, M is a transition metal having an atomic number greater than 40. Atomic number refers to the number of protons in the atomic nucleus of the chemical transition metal. More particularly, M is a transition metal selected from groups 8 to 10 of the Periodic Table. In various embodiments, M is selected from a group comprising iridium (Ir), ruthenium (Ru), osmium (Os), platinum (Pt), palladium (Pd) and rhenium (Rh). In a particular embodiment, M is iridium.

In at least one embodiment, the B2 ring is at least one aromatic or heteroaromatic. The B2 ring may be selected from a group comprising at least one fused aromatic, for example naphthalene, an unfused aromatic, for example benzene, a fused heteroaromatic, for example phenanthroline, and an unfused heteroaromatic, for example pyridine. The aromatic and/or heteroaromatic may be substituted or unsubstituted. “Unsubstituted” in respect of the B2 ring here means that the R₃₁, R₃₂, R₃₃ radicals are each hydrogen and EW is an electron-withdrawing substituent. “Substituted” here and hereinafter means that the rings have substituents other than hydrogen. In various embodiments, the B2 ring is a fluorinated phenyl having substitution on the B1 ring.

Alternatively or additionally, the aromatics or heteroaromatics may additionally be fused to further aromatic or nonaromatic rings. More particularly, the result in that case is a fused ring structure comprising at least one B2 ring having a carbon. In embodiments, the fused ring structure in that case is coordinated to transition metal M via an sp²-hybridized carbon atom.

In at least one embodiment, EW is at least one electron-withdrawing substituent. “Electron-withdrawing substituents” refers here and hereinafter to functional groups that can exert a —I effect, i.e. a negative inductive effect, via a sigma bond. More particularly, electron-withdrawing substituents may be halogens, for example fluorine (—F), chlorine (—Cl), bromine (—Br) or iodine (—I). In a particular embodiment, the electron-withdrawing substituent EW is a fluorine. Alternatively, the functional group may exert a -M effect, i.e. a negative mesomeric effect, via a n bond, for example via a nitro group (—NO₂). The electron-withdrawing substituent may, for example, also be a CN group.

The R₃₁, R₃₂, R₃₃ radicals may each independently be selected from a group comprising —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀,

where R₅₀, R₆₀, R₇₀, R₈₀, R₉₀, R₁₀₀, R₁₁₀, R₂₀₀, R₂₁₀, R₂₂₀, R₂₃₀ are each independently selected from a group comprising unbranched saturated hydrocarbon chains having one to 20 carbon atoms, branched saturated hydrocarbon chains having one to 20 carbon atoms, unbranched unsaturated hydrocarbon chains having one to 20 carbon atoms, branched unsaturated hydrocarbon chains having one to 20 carbon atoms, aromatic rings, nonaromatic rings, —H, —I, —Cl, —Br, —F, N+R₁₂₀R₁₃₀R₁₄₀, —SO₃R₁₅₀, —CN, —COCl, —COOR₁₆₀, —CR₁₇₀R₁₈₀OH, —CR₁₉₀O, —CHO and —COH,

where R₁₂₀, R₁₃₀, R₁₄₀, R₁₅₀, R₁₆₀, R₁₇₀, R₁₈₀, R₁₉₀ are each independently selected from a group comprising unbranched saturated hydrocarbon chains having one to 20 carbon atoms, branched saturated hydrocarbon chains having one to 20 carbon atoms and cyclic rings having 3 to 20 carbon atoms. More particularly, —CHO means an aldehyde group and —COH a hydroxyl group substituted on a carbon.

In at least one embodiment, EW is a fluorine and R₃₁ and/or R₃₂ is a fluorine. In a particular embodiment, EW is a fluorine and R₃₁, R₃₂ and R₃₃ are each hydrogen or EW and each R₃₂ is a fluorine and each R₃₁ and R₃₃ is hydrogen or EW and each R₃₁ is a fluorine and each R₃₂ and R₃₃ is hydrogen.

In at least one embodiment, the B1 ring is a nitrogen-containing ring. In a particular embodiment, the B1 ring is a pyridine substituted on the B2 ring. More particularly, the nitrogen of the pyridine is sp²-hybridized and coordinates to the transition metal M.

The nitrogen-containing ring may additionally be fused to further aromatic or nonaromatic rings. It is possible for a fused ring structure to be formed, comprising the B1 and B2 rings.

The B1 ring may be substituted or unsubstituted. “Unsubstituted” here and hereinafter means that the substituents, in the case of the B1 ring the R₄₁, R₄₂, R₄₃ and R₄₄ radicals, are each hydrogen. The terms “substituent” and “radical” are used synonymously here and hereinafter.

The R₄₁, R₄₂, R₄₃ and R₄₄ substituents selected may be the same or different. The R₄₁, R₄₂, R₄₃, R₄₄ radicals are each independently selected from a group comprising —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀. For R₅₀, R₆₀, R₇₀, R₈₀, R₉₀, R₁₀₀, R₁₁₀, R₂₀₀, R₂₁₀, R₂₂₀, R₂₃₀, the statements made above apply.

In at least one embodiment, the D1 ring and/or the D2 ring are each at least one nitrogen-containing ring. Each nitrogen-containing ring may optionally be fused to further aromatic or nonaromatic rings. The D1 and D2 rings may form a fused ring structure. In an embodiment, the ring structure is a substituted or unsubstituted 2,2′-bipyridine comprising the D1 and D2 rings. The 2,2′-bipyridine is preferably coordinated to the transition metal M via the two nitrogen atoms of the 2,2′-bipyridine. Alternatively, the fused ring structure is a substituted or unsubstituted 1,10-phenanthroline comprising the D1 ring and the D2 ring. The 1,10-phenanthroline is especially coordinated to the transition metal M via the two nitrogen atoms of the 1,10-phenanthroline. In that case in particular, the nitrogen atoms which form a coordinate bond to the transition metal M each have sp² hybridization.

The D1 ring may have R₁₁, R₁₂, R₁₃ and R₁₄ substituents. The R₁₁, R₁₂, R₁₃ and R₁₄ substituents selected may be the same or different. R₁₁, R₁₂, R₁₃ and R₁₄ may each independently be selected from a group comprising —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀. For R₅₀, R₆₀, R₇₀, R₈₀, R₉₀, R₁₀₀, R₁₁₀, R₂₀₀, R₂₁₀, R₂₂₀, R₂₃₀, the statements made above apply.

The D2 ring may have R₂₁, R₂₂, R₂₃ and R₂₄ substituents. The R₂₁, R₂₂, R₂₃ and R₂₄ substituents selected may be the same or different. R₂₁, R₂₂, R₂₃ and R₂₄ may each independently be selected from a group comprising —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀. For R₅₀, R₆₀, R₇₀, R₈₀, R₉₀, R₁₀₀, R₁₁₀, R₂₀₀, R₂₁₀, R₂₂₀, R₂₃₀, the statements made above apply.

More particularly, adjacent radicals such as the R₂₁ and R₁₄ radicals may have the —C═, —C═C—, —C═C, —C, N═C—, —N—C units and be bonded indirectly or directly to one another. In that case, the result is especially a fused ring structure.

In an embodiment, R₁₃ and R₂₂ are each a phenyl, tert-butyl or hydrogen. In addition, R₁₃ and R₂₂ may be the same, i.e. both be a phenyl, tert-butyl, methyl, methoxy or hydrogen.

The metal complex of the following structural formula III especially shows the nomenclature used according to the application for the positions of the individual atoms in the corresponding B1, B2, D1 and/or D2 rings:

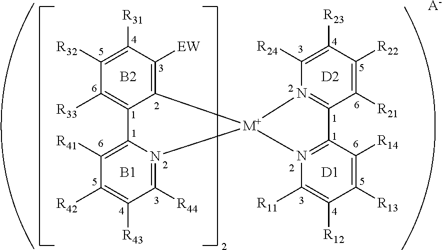

More particularly, the B1, B2, D1, D2 rings form a coordinate bond to the transition metal complex M at their respective 2 positions. More particularly, the B1 and B2 rings are joined to one another at least via their respective 1 positions. Correspondingly, the D1 and D2 rings are joined to one another via their respective 1 positions. The electron-withdrawing EW substituent is especially disposed at position 3 of the B2 ring. Alternatively, further electron-withdrawing substituents, preferably fluorine, may be attached at positions 4 and 5 of the B2 ring.

The metal complex of the structural formula IV is shown below.

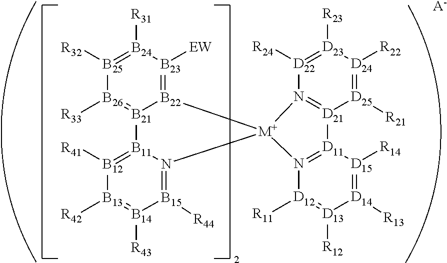

The structural formula IV shows that the atoms of the B1, B2, D1 and/or D2 rings need not necessarily have carbon atoms where they previously had carbon atoms according to structural formula I. For example, B₁₁, B₁₂, B₁₃, B₁₄, B₁₅, B₂₁, B₂₂, B₂₃, B₂₄, B₂₅, B₂₆, D₁₁, D₁₂, D₁₃, D₁₄, D₁₅, D₂₁, D₂₂, D₂₃, D₂₄, D₂₅ may independently be selected from nitrogen and carbon. More particularly, the B2 ring, as shown in the structural formula I, need not necessarily have carbon atoms at positions 1 to 6. Optionally, the B2 ring may also have nitrogen atoms at positions 1, 3, 4, 5 and/or 6. More particularly, B₂₂ is a carbon, in order not to alter the charge of M, since the ligands that are formed by the B1 and B2 rings are anionic ligands.

In at least one embodiment, A⁻ is a monovalent anion. In other words, A⁻ in particular is a singly negatively charged atom or molecule. More particularly, the monovalent anion is selected from a group including the following negatively charged elements or compounds: fluorine (F⁻), chlorine (Cl⁻), bromine (Br⁻), iodine (I⁻), NO₃⁻, NO₂⁻, BF₄⁻, PF₆⁻, CF₃SO₃⁻, CH₃SO₃⁻, Tf₂N⁻ (trifluoromethylsulfonimide). In a particular embodiment, A⁻ is a tetrafluorobromide (BF₄⁻) or hexafluorophosphate (PF₆⁻).

In at least one embodiment, the metal complex is ionic. What this means is that the central atom and the B1, B2, D1 and D2 rings form a positively charged molecule, i.e. a cation. Thus, it has a positive net charge. This positive net charge can be compensated for by a counterion, especially by the monovalent anion.

In at least one embodiment, the metal complex has been set up to emit radiation from the green to yellow spectral region. The green spectral region refers here and hereinafter to a wavelength range from 510 to 550 nm, for example 530 nm. The yellow-green spectral region refers here and hereinafter to a wavelength range from 551 nm to 570 nm, for example 556 nm. The yellow spectral region refers here and hereinafter to a wavelength range between 571 nm and 595 nm, for example 580 nm. The emission of the radiation is especially dependent on the morphology of the sample, for example whether the sample is in powder or solution form.

In at least one embodiment of the metal complex, EW is a fluorine. In addition, the R₃₁, R₃₂, R₃₃, R₄₁, R₄₂, R₄₃, R₄₄, R₂₁, R₂₂, R₂₃, R₂₄, R₁₄, R₁₃, R₁₂, R₁₁ radicals may each be hydrogen. The result may be, for example when the transition metal M is iridium and the monovalent anion A⁻ is PF₆⁻, the following structural formula V:

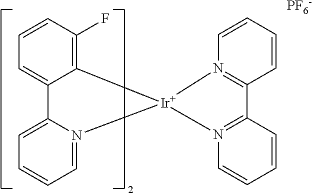

PF₆⁻ and Ir in the structural formula V here are merely examples and may also be replaced by other transition metals M or monovalent anions A⁻. Instead of F, it is also possible to use another electron-withdrawing substituent.

The metal complex of the structural formula V may be referred to as [iridium(3-fluorophenylpyridinato)2(2,2′-bipyridine)]PF₆.

In at least one embodiment, the metal complex may have a fluorine as EW. In particular, fluorine is substituted at position 3 of the B2 ring. The R₃₁, R₃₂, R₃₃, R₄₁, R₄₂, R₄₃, R₄₄, R₂₄, R₂₃, R₂₁, R₁₄, R₁₂ and R₁₁ radicals may each be hydrogen. The R₂₂ and R₁₃ radicals may each be a tertiary butyl radical. More particularly, the metal complex may have the following structural formula VI, for example when the transition metal M is iridium and the monovalent anion A⁻ is PF₆⁻:

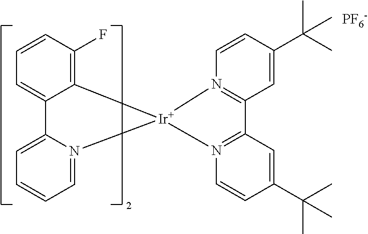

PF₆⁻ and Ir in the structural formula VI here are merely examples and may also be replaced by other transition metals M or monovalent anions A⁻. Instead of F, it is also possible to use another electron-withdrawing substituent.

The metal complex of the structural formula VI may be referred to as [iridium(3-fluorophenylpyridinato)2(4,4′-di-tert-butyl-2,2′-bipyridine)]PF₆.

In at least one embodiment, the electron-withdrawing substituent EW has a fluorine at position 3 of the B2 ring. More particularly, the R₃₁, R₃₂, R₃₃, R₄₁, R₄₂, R₄₃, R₄₄, R₂₁, R₂₂, R₂₃, R₂₄, R₁₄, R₁₃ and R₁₂ radicals are each hydrogen. The R₁₁ radical is a phenyl radical. The result is the following structural formula VII, for example when the transition metal M is iridium and the monovalent anion is a [PF₆]⁻:

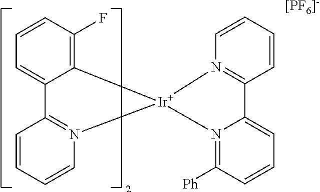

PF₆⁻ and Ir in the structural formula VII here are merely examples and may also be replaced by other transition metals M or monovalent anions A⁻. Instead of F, it is also possible to use another electron-withdrawing substituent.

The metal complex of the structural formula VII may be referred to as [iridium(3-fluorophenylpyridinato)2(6-phenyl-2,2′-bipyridine)]PF₆.

In at least one embodiment, the metal complex has one fluorine each at position 3 of the B2 ring as EW and at position 5 of the B2 ring as substituent R₃₂. In particular, the rest of the substituents of the B1, B2, D1, D2 rings are each hydrogen. Using the example of the transition metal M iridium and the monovalent anion PF₆⁻, the result is a metal complex of the following structural formula VIII:

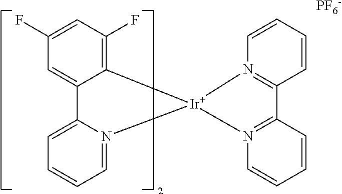

PF₆⁻ and Ir in the structural formula VIII here are merely examples and may also be replaced by other transition metals M or monovalent anions A⁻. Instead of F, it is also possible to use another electron-withdrawing substituent.

The metal complex of the structural formula VIII may be referred to as [iridium(3,5-difluorophenylpyridinato)2(2,2′-bipyridine)]PF₆.

In at least one embodiment, the metal complex has one fluorine each as electron-withdrawing substituent EW at position 3 of the B2 ring and at position 5 of the B2 ring as R₃₂ radical. The rest of the substituents of the B1, B2, D1, D2 ring except for the R₂₂ and R₁₃ substituents may be substituted by hydrogen. The R₂₂ and R₁₃ substituents may each be a tertiary butyl radical. Using the example of the transition metal M iridium and the monovalent anion PF₆⁻, the result is the following structural formula IX:

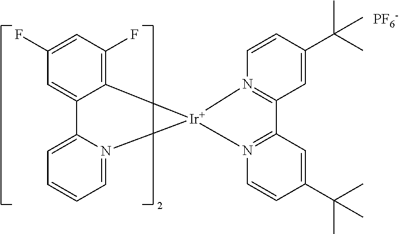

PF₆⁻ and Ir in the structural formula IX here are merely examples and may also be replaced by other transition metals M or monovalent anions A⁻. Instead of F, it is also possible to use another electron-withdrawing substituent.

The metal complex of the structural formula IX may be referred to as [iridium(3,5-difluorophenylpyridinato)2(4,4′-di-tert-butyl-2,2′-bipyridine)]PF₆.

In at least one embodiment, the metal complex has one fluorine each at positions 3 and 5 of the B2 ring. In addition, the metal complex has a phenyl as R₁₁ substituent at position 3 of the D1 ring. The other radicals of the B1, B2, D1 and D2 rings may each be substituted by hydrogen. Using the example of the transition metal M iridium and the monovalent anion [PF₆⁻], the result is the following structural formula X:

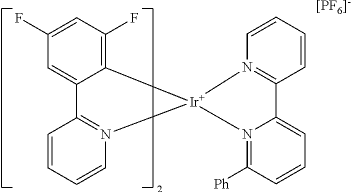

PF₆⁻ and Ir in the structural formula X here are merely examples and may also be replaced by other transition metals M or monovalent anions A⁻. Instead of F, it is also possible to use another electron-withdrawing substituent.

The metal complex of the structural formula X may be referred to as [iridium(3,5-difluorophenylpyridinato)2(6-phenyl-2,2′-bipyridine)]PF₆.

In at least one embodiment, the metal complex has one fluorine each at positions 3 and 4 of the B2 ring. The rest of the substituents of the B1, B2, D1, D2 ring except for the R₂₂ and R₁₃ substituents may each be substituted by hydrogen. The R₁₃ and R₂₂ substituents may each have a tertiary butyl radical. Using the example of the transition metal iridium and the monovalent anion PF₆⁻, the result is a metal complex of the following structural formula XI:

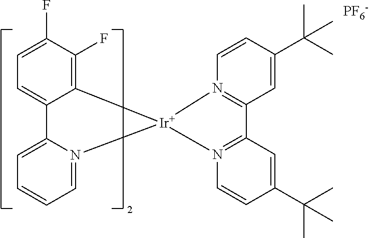

PF₆⁻ and Ir in the structural formula XI here are merely examples and may also be replaced by other transition metals M or monovalent anions A⁻. Instead of F, it is also possible to use another electron-withdrawing substituent.

The metal complex of the structural formula XI may be referred to as [iridium(3,4-difluorophenylpyridinato)2(4,4′-di-tert-butyl)-2,2′-bipyridine)]PF₆.

In at least one embodiment, the metal complex may have fluorine as electron-withdrawing substituent EW. In particular, fluorine is substituted at position 3 of the B2 ring. The R₃₁, R₃₂, R₃₃, R₄₁, R₄₂, R₄₃, R₄₄, R₂₄, R₂₃, R₂₁, R₁₄, R₁₂ and R₁₁ radicals may each be hydrogen. The R₂₂ and R₁₃ radicals may each be a methyl. More particularly, the metal complex may have the following structural formula XX, for example when the transition metal M is iridium and the monovalent anion A⁻ is PF₆⁻:

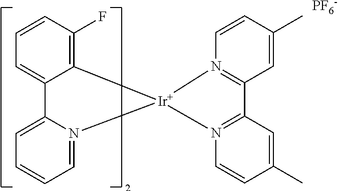

PF₆⁻ and Ir in the structural formula XX here are merely examples and may also be replaced by other transition metals M or monovalent anions A⁻. Instead of F, it is also possible to use another electron-withdrawing substituent.

The metal complex of the structural formula XX may be referred to as [iridium(3-fluorophenylpyridinato)2(4,4′-dimethyl-2,2′-bipyridine)]PF₆.

In at least one embodiment, the metal complex may have fluorine as electron-withdrawing substituent EW. In particular, fluorine is substituted at position 3 of the B2 ring. The R₃₁, R₃₂, R₃₃, R₄₁, R₄₂, R₄₃, R₄₄, R₂₄, R₂₃, R₂₁, R₁₄, R₁₂ and R₁₁ radicals may each be hydrogen. The R₂₂ and R₁₃ radicals may each be a methoxy radical. More particularly, the metal complex may have the following structural formula XXI, for example when the transition metal M is iridium and the monovalent anion A⁻ is PF₆⁻:

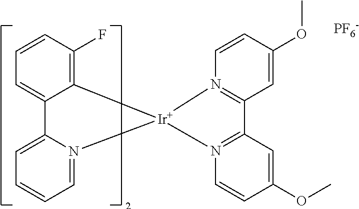

PF₆⁻ and Ir in the structural formula XXI here are merely examples and may also be replaced by other transition metals M or monovalent anions A⁻. Instead of F, it is also possible to use another electron-withdrawing substituent.

The metal complex of the structural formula XXI may be referred to as [iridium(3-fluorophenylpyridinato)2(4,4′-dimethoxy-2,2′-bipyridine)]PF₆.

In at least one embodiment, the metal complex may have fluorine as electron-withdrawing substituent EW. In particular, fluorine is substituted at position 3 of the B2 ring. The R₃₁, R₃₂, R₃₃, R₄₁, R₄₂, R₄₃, R₄₄, R₂₄, R₂₂, R₂₁, R₁₄, R₁₃ and R₁₁ radicals may each be hydrogen. The R₂₃ and R₁₂ radicals may each be a methyl radical. More particularly, the metal complex may have the following structural formula XXII, for example when the transition metal M is iridium and the monovalent anion A⁻ is PF₆⁻:

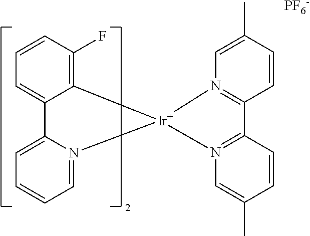

PF₆⁻ and Ir in the structural formula XXII here are merely examples and may also be replaced by other transition metals M or monovalent anions A⁻. Instead of F, it is also possible to use another electron-withdrawing substituent.

The metal complex of the structural formula XXII may be referred to as [iridium(3-fluorophenylpyridinato)2(5,5′-dimethyl-2,2′-bipyridine)]PF₆.

In other words, the metal complex has an electron-withdrawing substituent, preferably fluorine, at least at position 3 of the B2 ring. Alternatively or additionally, as well as this electron-withdrawing substituent at position 3 of the B2 ring, a further electron-withdrawing substituent on the B2 ring may be substituted. In a particular embodiment, the further electron-withdrawing substituent is a fluorine which is especially substituted at the 4 or 5 position of the B2 ring. In this way, it is possible to provide a metal complex having high structural stability.

In at least one embodiment, the metal complex has the following structural formula II:

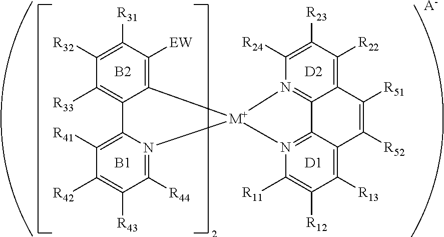

where M, the B2 ring, the B1 ring, the D1 ring, the D2 ring, A, EW, R₁₁, R₁₂, R₁₃, R₂₂, R₂₃, R₂₄, R₄₁, R₄₂, R₄₃, R₄₄, R₃₁, R₃₂ and R₃₃ are each as defined for structural formula I. R₅₁ and R₅₂ are each selected independently from a group comprising —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀. In a particular embodiment, EW is fluorine.

In a further particular embodiment, EW and/or R₃₂ are each a fluorine. Alternatively, EW and/or R₃₁ are each a fluorine.

In this context, all the definitions and embodiments cited above for the metal complex of the structural formulae I to XI and XX to XXII also apply to the metal complex of the structural formula II, and vice versa.

In at least one embodiment, the metal complex of the structural formula II has one fluorine each for EW and R₃₂. Alternatively, the metal complex of the structural formula II has one fluorine each for EW and R₃₁.

In at least one embodiment, the metal complex of the structural formula II independently has one phenyl, tert-butyl, methyl, methoxy or hydrogen each for R₁₃ and R₂₂. More particularly, R₁₃ and R₂₂ are the same.

In at least one embodiment, the R₁₁ and/or R₂₄ radicals for the metal complex of the structural formula II are each methyl.

In at least one embodiment, the metal complex of the structural formula II has a fluorine at position 3 of the B2 ring as electron-withdrawing substituent EW. The other R₃₁, R₃₂, R₃₃, R₄₁, R₄₂, R₄₃, R₄₄, R₅₁, R₅₂, R₂₄, R₂₃, R₂₂, R₁₃, R₁₂ and R₁₁ substituents may each be hydrogen. The R₂₁ radicals of the D2 ring and R₁₄ radicals of the D1 ring are joined to one another by a double bond and hence form at least one fused aromatic ring system composed of at least three rings. The D1 and D2 rings are thus part of the fused aromatic ring system. More particularly, the fused aromatic ring system is a phenanthroline. Using the example of iridium as transition metal and PF₆⁻ as monovalent anion, the result is the following structural formula XII:

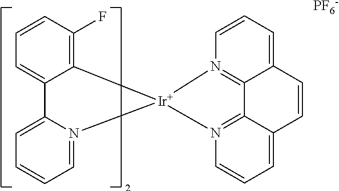

PF₆⁻ and Ir in the structural formula XII here are merely examples and may also be replaced by other transition metals M or monovalent anions A⁻. Instead of F, it is also possible to use another electron-withdrawing substituent.

The metal complex of the structural formula XII may be referred to as [iridium(3-fluorophenylpyridinato)2(phenanthroline)]PF₆.

In at least one embodiment, the metal complex of the structural formula II has a fluorine at position 3 of the B2 ring. The rest of the substituents of the B2 ring and also those of the B1 ring may be substituted by hydrogen. The substituents of the D2 ring, i.e. R₂₃ and R₂₄, and the substituents of the D1 ring, i.e. R₁₁ and R₁₂, may each be a hydrogen. The R₂₂ and R₁₃ substituents may each be a phenyl radical. The result is a metal complex of the following structural formula XIII, showing here, by way of example, iridium as transition metal and [PF₆] as monovalent anion:

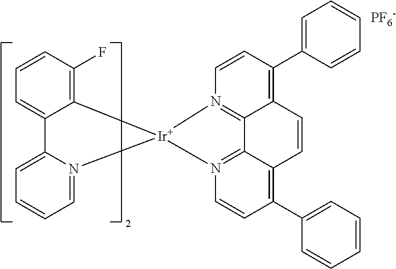

PF₆⁻ and Ir in the structural formula XIII here are merely examples and may also be replaced by other transition metals M or monovalent anions A⁻. Instead of F, it is also possible to use another electron-withdrawing substituent.

The metal complex of the structural formula XIII may be referred to as [iridium(3-fluorophenylpyridinato)2(bathophenanthroline)]PF₆.

In at least one embodiment, the metal complex of the structural formula II has a fluorine at position 3 of the B2 ring. The R₂₄ and R₁₁ substituents of the D1 and D2 rings may each be substituted by a methyl radical. The R₂₂ and R₁₃ substituents may each be a phenyl radical. The remaining substituents of the B1, B2, D1 and D2 rings may each be hydrogen. The result is the following structural formula XIV having, by way of example, iridium as transition metal and the monovalent anion PF₆⁻.

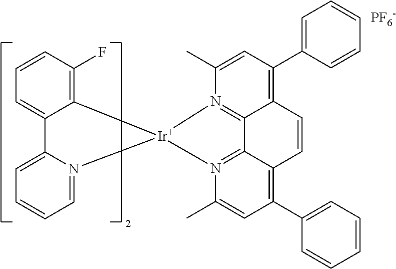

PF₆⁻ and Ir in the structural formula XIV here are merely examples and may also be replaced by other transition metals M or monovalent anions A⁻. Instead of F, it is also possible to use another electron-withdrawing substituent.

The metal complex of the structural formula XIV may be referred to as [iridium(3-fluorophenylpyridinato)2(bathocuproin)]PF₆.

In at least one embodiment, the metal complex of the structural formula II has one electron-withdrawing substituent, preferably fluorine, at each of positions 3 and 5 of the B2 ring. The remaining substituents of the B1, B2, D1, D2 rings may each be hydrogen. The result is a metal complex of the following structural formula XV having, by way of example, iridium as transition metal and PF₆⁻ as monovalent anion:

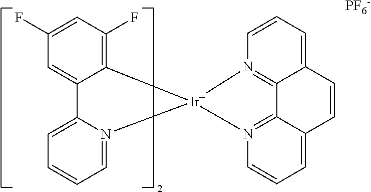

PF₆⁻ and Ir in the structural formula XV here are merely examples and may also be replaced by other transition metals M or monovalent anions A⁻. Rather than F as EW and/or R₃₂, it is also possible to use other electron-withdrawing substituents.

The metal complex of the structural formula XV may be referred to as [iridium(3,5-difluorophenylpyridinato)2(phenanthroline)]PF₆.

In at least one embodiment, the metal complex of the structural formula II has one fluorine each at position 3 and at position 5 of the B2 ring. The R₂₂ and R₁₃ substituents may each be a phenyl. In addition, the phenyl may be substituted or unsubstituted. Using the example of the following structural formula XVI, the result is a metal complex having, for example, iridium as transition metal and PF₆⁻ as monovalent anion:

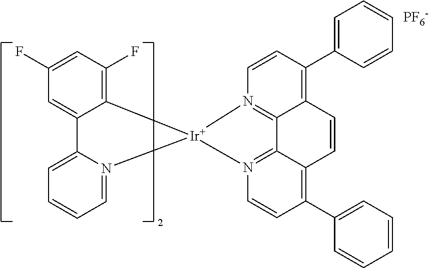

PF₆⁻ and Ir in the structural formula XVI here are merely examples and may also be replaced by other transition metals M or monovalent anions A⁻. Rather than F as EW and/or R₃₂, it is also possible to use other electron-withdrawing substituents.

The metal complex of the structural formula XVI may be referred to as [iridium(3,5-difluorophenylpyridinato)2(bathophenanthroline)]PF₆.

In at least one embodiment, the metal complex of the structural formula II has an electron-withdrawing substituent, especially fluorine, at positions 3 and 5 of the B2 ring. The R₂₄ and R₁₁ substituents may be an alkyl radical, especially methyl. The rest of the substituents may be hydrogen. The result is the following structural formula XVII for the metal complex having, for example, iridium as transition metal and PF₆⁻ as monovalent anion.

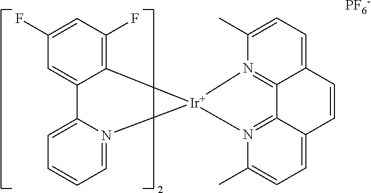

PF₆⁻ and Ir in the structural formula XVII here are merely examples and may also be replaced by other transition metals M or monovalent anions A⁻. Rather than F as EW and/or R₃₂, it is also possible to use other electron-withdrawing substituents.

The metal complex of the structural formula XVII may be referred to as [iridium(3,5-difluorophenylpyridinato)2(2,9-dimethylphenanthroline)]PF₆.

In at least one embodiment, the metal complex of the structural formula II has an electron-withdrawing substituent in each case, especially fluorine in each case, at positions 3 and 4 of the B2 ring. The R₂₂ and R₁₃ substituents may each be phenyl. The rest of the substituents may, for example, be hydrogen. The result is the following structural formula XVIII for the metal complex having, for example, iridium as transition metal and PF₆⁻ as monovalent anion:

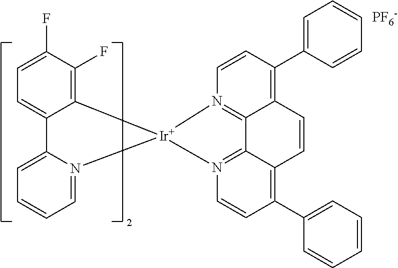

PF₆⁻ and Ir in the structural formula XVIII here are merely examples and may also be replaced by other transition metals M or monovalent anions A⁻. Rather than F as EW and/or R₃₁, it is also possible to use other electron-withdrawing substituents.

The metal complex of the structural formula XVIII may be referred to as [iridium(3,4-difluorophenylpyridinato)2(bathophenanthroline)]PF₆.

In at least one embodiment, the metal complex of the structural formula II has one electron-withdrawing substituent, preferably fluorine, at each of positions 3 and 4 of the B2 ring. The remaining substituents of the B1, B2, D1, D2 rings of the structural formula II may especially be hydrogen. The result is a structural formula XIX which shows, for example, iridium as transition metal and [PF₆]⁻ as monovalent anion.

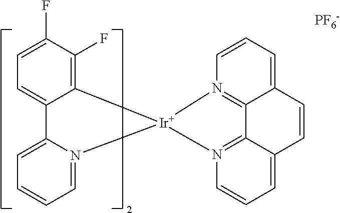

PF₆⁻ and Ir in the structural formula XIX here are merely examples and may also be replaced by other transition metals M or monovalent anions A⁻. Rather than F as EW and/or R₃₁, it is also possible to use other electron-withdrawing substituents.

The metal complex of the structural formula XIX may be referred to as [iridium(3,4-difluorophenylpyridinato)2(phenanthroline)]PF₆.

The inventors have recognized that the metal complexes of the structural formulae I to XXII have high structural stability. More particularly, the metal complexes have high stability at high temperatures or during the operation of a light-emitting organic component.

The structural stability of metal complexes, especially of ionic transition metal complexes, is caused by a strong sigma anti-bonding interaction between the transition metal atom, for example the iridium atom, and the nitrogen atom of the B1 ring. This strong anti-bonding interaction between the unoccupied e_{g} orbital of the iridium and the unhybridized orbital of the sp² nitrogen of the B1 ring becomes stronger during the operation of an organic light-emitting component. The population of the e_{g} orbital (³MC level), during the operation of an organic light-emitting component, leads to an enhancement of the σ anti-bonding interactions and hence to elongation of the transition metal complex-nitrogen bond of the B1 ring, which leads to opening of the molecular structure and hence facilitates the access of small nucleophilic molecules and leads to degradation. In other words, the iridium-nitrogen bond of the B1 ring is broken. The degradation process can be increased by intermolecular interaction.

In principle, two approaches are possible to solve this problem. Firstly, it would be possible to produce a metal complex which forms π-π stacking between a phenyl ring of the D1-D2 ring system and a fluorinated or unfluorinated phenyl ring of the B1-B2 ring system. This results in a cage structure. This cage structure can prevent the extreme elongation of the iridium-nitrogen bond of the B1 ring during the operation of the component and hence reduce possible nucleophilic attacks, i.e., for example, by water molecules or by Cl—, on the transition metal. The result is rising molecular stability of the metal complex.

Secondly, it would also be possible to produce individual fluorinated substituents at the 3 position of the phenyl ring of the B2 ring, i.e. in the ortho position to the carbon that forms a coordinate bond to the transition metal complex. With these fluorinated substituents, intramolecular interactions between the two B1 and B2 rings and an individual ionic transition metal complex molecule are possible. The ionic transition metal complexes with their preferred fluorine-nitrogen interactions likewise form molecular cage structures and hence prevent extreme elongation of the iridium-nitrogen bond of the B1 ring. This reduces the possibility of nucleophilic attack on the transition metal complex, for example by water or Cl⁻, and increases molecular stability during the operation of the component. These specific F—N intramolecular interactions can be measured or visualized by means of x-ray single crystal structure analysis.

The invention further relates to a process for preparing a metal complex. In various embodiments, the process prepares the metal complex. Thus, all the definitions and embodiments cited for the metal complex also apply to the process, and vice versa.

This process for preparing a metal complex has the process steps of:

A) providing a transition metal M which is part of a central atom compound,

B) mixing the central atom compound in ligands dissolved in solvent to form a metal complex, where the ligands comprise the rings B1, B2, D1 and D2, and the rings B1, B2, D1, D2 each form a coordinate bond to the central atom or transition metal.

In at least one embodiment, the metal complex is purified by column chromatography.

For example, a metal complex of the structural formula I can be prepared as follows:

Ligand Synthesis

Ligands comprising at least the B1 and B2 rings can be prepared by a Suzuki coupling, as shown, for example, in L. Chun et al., Eur. J. Org. Chem., 2010, 29, pages 5548 to 5551. The disclosure content relating to the preparation in Chun et al. is hereby incorporated by reference. To a mixture of 2-pyridyl bromide (for example 2-bromopyridine, 1 eq.), potassium phosphate (2 eq.) and Pd(OAc)₂ (0.5 mol % of 1 eq.) in ethylene glycol is added an appropriate proportion of a fluorinated arylboronic acid (1.3 eq.). The mixture is boiled under reflux at 80° C. for 24 hours. The mixture can be cooled down to room temperature. Subsequently, a salt solution can be added and the mixture can be extracted with diethyl ether. The contents in the ether can be concentrated and the crude ligand can be obtained as a viscous liquid. The ligands are purified by column chromatography. A colorless liquid or a white powder is formed.

Chlorine-Bridged Intermediate of Diiridium Complexes

Chlorine-bridged dimetallic complexes can be synthesized as published in E. Holder et al., 2005, Adv. Mater. 2005, 17, pages 1109-1121. The disclosure content of Holder et al. in relation to the synthesis is hereby incorporated by reference. IrCl₃×H₂O (1 eq.) is introduced into a Schlenk vessel in an argon glovebox. Water and 2-methoxyethanol are added. This can be effected by means of a cannula. During this, the reaction mixture is stirred. The required ligands comprising the B1 and B2 rings (2.15 eq.) are added and this reaction mixture is boiled at 120° C. for 18 hours under pressure-regulating conditions at reflux. The mixture can be cooled down to room temperature and precipitated. The precipitate is filtered and washed with water and diethyl ether. The precipitate formed is subsequently dried under reduced pressure. The synthesis and the operations are conducted under inert gas atmosphere.

Ionic Heteroleptic Iridium Complexes

Metal complexes, especially light-emitting ionic iridium complexes, are synthesized as disclosed in J. D. Slinker et al., J. Am. Chem. Soc., 2004, 126, pages 2736-2767. The disclosure content of Slinker et al. in relation to the synthesis is hereby incorporated by reference. The required proportions of the ligands comprising the D1 and D2 rings (2.15 eq.) and the chlorine-bridged iridium dimers (1 eq.) are transferred into a Schlenk vessel in an argon glovebox. Ethylene glycol is added, for example by means of a cannula, and the reaction mixture is boiled at 150° C. for 20 hours (under reflux and pressure-regulating conditions). This forms a clear solution. The solution can be cooled down to room temperature and introduced into another Schlenk vessel comprising distilled water. The excess of the aqueous solution of ammonium hexafluorophosphate (NH₄PF₆) is added to this aqueous solution, so as to result in an intermediate as precipitate of the desired heteroleptic iridium complex. The product is filtered and washed with water and diethyl ether and then dried under reduced pressure. The synthesized complex is purified by means of column chromatography. The product obtained is dried under reduced pressure. The synthesis, the operations and the purification are conducted under inert gas atmosphere.

The invention further relates to an organic light-emitting component. In various embodiments, the organic light-emitting component comprises the metal complex. Thus, all the definitions and embodiments cited for the metal complex also apply to the organic light-emitting component, and vice versa.

In at least one embodiment, the organic light-emitting component has at least one organic light-emitting layer between two electrodes. The organic light-emitting layer includes a metal complex, preferably the above-described metal complex, as emitter material.

In at least one embodiment, the organic light-emitting component is an organic light-emitting diode (OLED). Alternatively, the organic light-emitting component may be an organic light-emitting electrochemical cell (OLEC). The organic light-emitting component has at least one organic light-emitting layer. More particularly, the organic light-emitting component has been set up to emit radiation from the green to yellow spectral region.

An organic light-emitting electrochemical cell generally differs from an organic light-emitting diode in that the electrochemical cell has just one organic light-emitting layer between the two electrodes. In other words, the electrochemical cell does not have any further layers, especially injection layers, transport layers and/or blocker layers. Thus, the organic light-emitting electrochemical cell has a simpler structure compared to an organic light-emitting diode. By contrast, the organic light-emitting diode generally has a functional layer stack.

The functional layer stack may include layers comprising organic polymers, organic oligomers, organic monomers, organic small non-polymeric molecules (“small molecules”) or combinations thereof. The functional layer stack may have, in addition to the at least one organic light-emitting layer, a further functional layer executed in the form of a hole transport layer, in order to enable effective hole injection in at least the organic light-emitting layer. Advantageous materials for a hole transport layer may be found, for example, to be tertiary amines, carbazole derivatives, camphorsulfonic acid-doped polyaniline or polystyrenesulfonic acid-doped polyethylenedioxythiophene. The functional layer stack may further include at least one functional layer which takes the form of an electron transport layer. In general, the functional layer stack may have, in addition to the organic light-emitting layer, further layers selected from hole injection layers, hole transport layers, electron injection layers, electron transport layers, hole blocker layers and electron blocker layers.

In at least one embodiment, the organic light-emitting component has at least two electrodes. More particularly, the functional layer stack is arranged between the two electrodes.

In at least one embodiment, at least one of the electrodes is transparent. “Transparent” refers here and hereinafter to a layer which is transparent in respect of visible light. The transparent layer may be clearly translucent or at least partly light-scattering and/or partly light-absorbing, such that the transparent layer may, for example, also have diffuse or milky translucency. More preferably, a layer referred to here as transparent has maximum transparency, such that, more particularly, the absorption of light or radiation generated in the functional layer stack in the course of operation of the component is as small as possible.

In at least one embodiment, both electrodes are transparent. Thus, the light generated in the organic light-emitting layer can be emitted in both directions, i.e. through both electrodes. In other words, the device is a transparent OLED or OLEC. Alternatively, the light can also be emitted in just one direction, for example through an electrode facing the substrate. In this case, reference is also made to a bottom emitter. If the light is emitted through the electrode facing away from the substrate, reference is also made to a top emitter.

The material used for a transparent electrode may, for example, be a transparent conductive oxide. Transparent conductive oxides (“TCOs” for short) are generally metal oxides, for example zinc oxide, tin oxide, cadmium oxide, titanium oxide, indium oxide or indium tin oxide (ITO). As well as binary metal-oxygen compounds, for example ZnO, SnO₂ or In₂O₃, the group of the TCOs also includes ternary metal-oxygen compounds, for example Zn₂SnO₄, CdSnO₃, ZnSnO₃, MgIn₂O₄, GaInO₃, Zn₂In₂O₅ or In₄Sn₃O₁₂, or mixtures of different transparent conductive oxides. At the same time, the TCOs do not necessarily correspond to a stoichiometric composition and may additionally be p- or n-doped. More particularly, the transparent material is indium tin oxide (ITO).

The second electrode, which is especially in non-transparent form, may, for example, be the cathode and may consist of or comprise aluminum, barium, indium, silver, gold, magnesium, calcium or lithium, and combinations or alloys thereof. The material for the second electrode is especially air-stable and/or non-reactive. It is thus possible to dispense with hermetic sealing of the organic light-emitting component. This saves costs and time in the production of the organic light-emitting component.

In at least one embodiment, the organic light-emitting layer is arranged in direct contact with the first electrode and with the second electrode. “Direct contact” is understood here to mean especially direct mechanical and/or electrical contact.

In at least one embodiment, the organic light-emitting component has a substrate. More particularly, one of the two electrodes is disposed on the substrate. The substrate may, for example, include one or more materials in the form of a layer, a sheet, a film or a laminate, these being selected from glass, quartz, plastic, metal, silicon, wafer. More particularly, the substrate includes or consists of glass.

In at least one embodiment, the at least one organic light-emitting layer has been set up to emit radiation from the green to yellow spectral region. In an embodiment, the dominant wavelength of the green wavelength range has a value of 530 nm with a tolerance of 20 nm from this value. In a further embodiment, the dominant wavelength of the yellow-green wavelength range has a value of 560 nm with a tolerance of 10 nm from this value. In other embodiments, the dominant wavelength of the yellow spectral region has a value of 580 nm with a tolerance of 10 nm from this value. Dominant wavelength refers to the wavelength that describes the hue of an OLED or OLEC as perceived by the human eye.

In at least one embodiment, the component emits radiation from the green to yellow spectral region.

In at least one embodiment, the organic light-emitting component has an encapsulation. The encapsulation is preferably applied in the form of a thin-film encapsulation to the organic light-emitting component. More particularly, the encapsulation protects the functional layer stack or at least the organic light-emitting layer and the electrodes from the environment, for example from moisture and/or oxygen and/or other corrosive substances, for instance hydrogen sulfide. The encapsulation may include one or more thin layers applied, for example, by means of chemical vapor deposition (CVD). For example, the encapsulation may be a glass lid that has been stuck on.

The inventors have recognized that the metal complex of at least the structural formula I can provide an efficient and inexpensive emitter material for an organic light-emitting component. More particularly, the organic light-emitting component may have a flexible size. The organic light-emitting component can be employed in packaging or lighting.

In at least one embodiment, the organic light-emitting layer has been produced from the liquid phase. More particularly, the treatment can be effected by a solution-based process, such as a roll-to-roll process, spin-coating or printing method.

In at least one embodiment, the metal complex is homogeneously distributed in a matrix material. Alternatively, the metal complex may also have a concentration gradient in the matrix material. The matrix material may, for example, be TCTA, tris(4-carbazol-9-yl)triphenylamine, or CBP, 4,4′-bis(N-carbazolyl)-1,1′-biphenyl.

In at least one embodiment, the matrix material includes further additional materials which may be uncharged or have an ionic charge. For example, the further material may be an ionic liquid. An example of an ionic liquid that can be used is 1-butyl-3-methylimidazolium hexafluorophosphate.

In at least one embodiment, the metal complex is distributed within the matrix material at least to an extent of 60% by weight, especially to an extent of 80% by weight, preferably more than 90% by weight.

### BRIEF DESCRIPTION OF THE DRAWINGS

Further advantages, advantageous embodiments and developments will be apparent from the working examples described hereinafter in conjunction with the figures.

The figures show:

FIG. 1 shows a schematic side view of an organic light-emitting component in one embodiment,

FIG. 2 shows a schematic side view of an organic light-emitting component in one embodiment,

FIGS. 3A and B each show an x-ray crystal structure analysis of one embodiment,

FIGS. 4A, 4B, 5A, 5B, 6A, 6B, 7, 8, 9 and 10 each show an emission spectrum of one embodiment and

FIG. 11 shows a luminescence spectrum of one embodiment, and

FIG. 12 shows the efficiency as a function of time in one embodiment.

In the working examples and figures, elements that are identical or of the same type or have the same effect may each be given the same reference signs. The elements shown and their size ratios relative to one another should not be regarded as being to scale. Instead, individual elements, for example layers, parts, components and regions, may be shown in excessively large size for better reproducibility and/or for better understanding.

### DETAILED DESCRIPTION OF ILLUSTRATIVE EMBODIMENTS

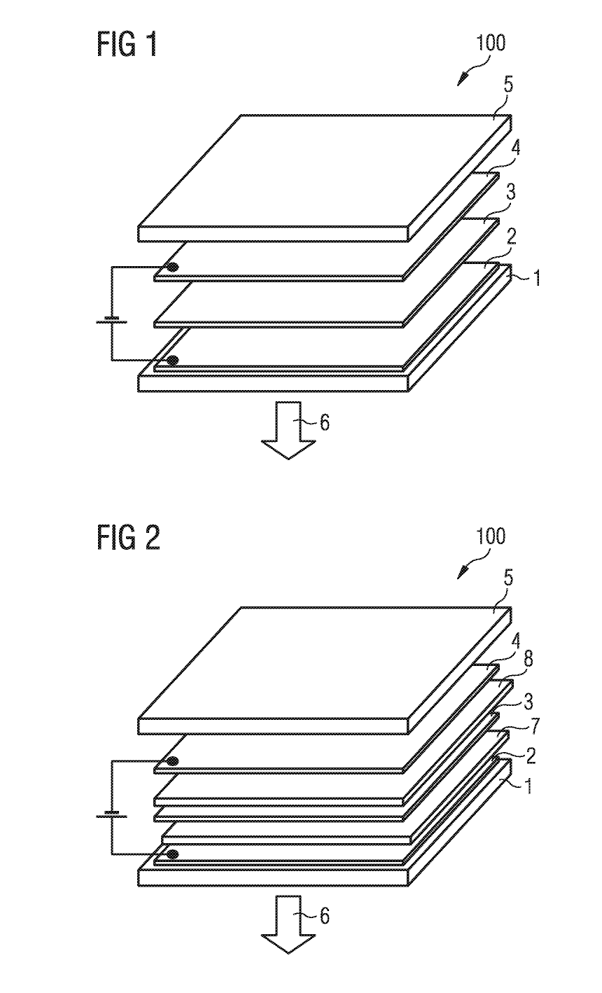

FIG. 1 shows a schematic side view of an optoelectronic component in one embodiment. The organic light-emitting component 100 has a substrate 1. The substrate 1 may be formed, for example, from glass. A first electrode 2 is arranged directly alongside the substrate 1. The first electrode 2 may be formed, for example, from a transparent conductive material, for example ITO. More particularly, the first electrode 2 has a layer thickness of 100 to 150 nm. The first electrode 2 is followed by an organic light-emitting layer. The organic light-emitting layer 3 has the metal complex at least of the structural formula I as emitter material. The metal complex may be embedded in a matrix material. The embedding can be effected in a homogeneous manner or by means of a concentration gradient. The organic light-emitting layer 3 is followed by a second electrode 4. The second electrode 4 may, for example, be in reflective form. The second electrode 4 may have a layer thickness, for example, of 130 nm. More particularly, only the organic light-emitting layer 3 is arranged between the first electrode 2 and the second electrode 4, and so no further layers are arranged therebetween. In other words, the organic light-emitting component takes the form of an organic light-emitting electrochemical cell (OLEC). The second electrode 4 may be followed by an encapsulation 5. More particularly, the organic light-emitting component 100 may take the form of a bottom emitter; in other words, the radiation generated in the organic light-emitting layer 3 is emitted in the direction of the first electrode 2 through the first substrate 1 (arrow 6).

FIG. 2 shows a schematic side view of an organic light-emitting component in one embodiment. The organic light-emitting component 100 of FIG. 2 differs from the organic light-emitting component 100 of FIG. 1 in that it has further layers between the first electrode 2 and the second electrode 4. More particularly, a further layer 7 is arranged between the first electrode 2 and the organic light-emitting layer 3. For example, the further layer 7 may be a hole injection layer. A further layer 8, for example an electron transport layer, may be arranged between the organic light-emitting layer 3 and the second electrode 4. More particularly, the component 100 according to FIG. 2 is an OLED.

Alternatively, the components 100 of FIGS. 1 and 2 may also take the form of top emitters or of transparent components.

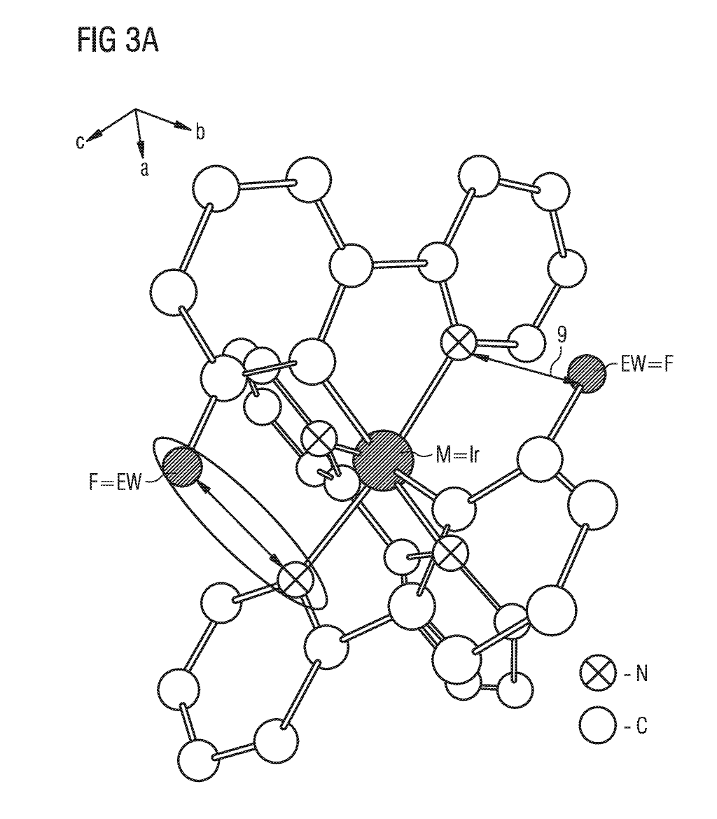

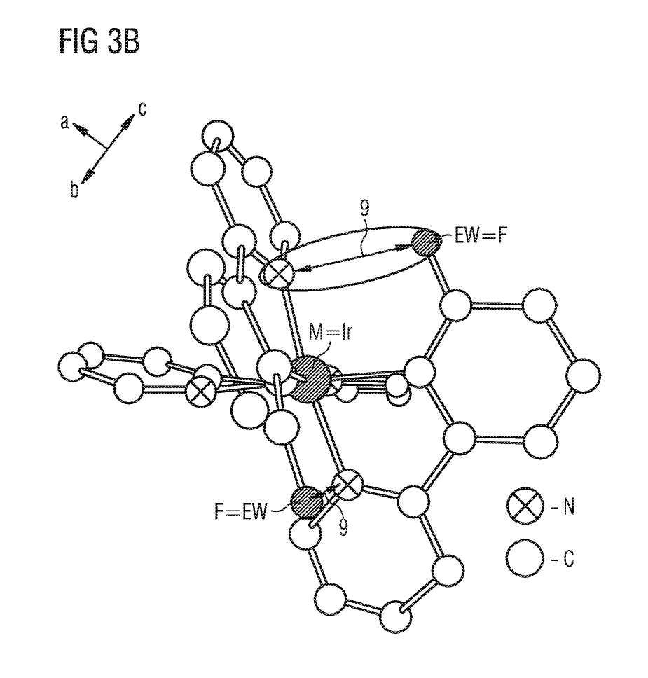

FIGS. 3A and 3B show an x-ray single crystal structure analysis of a working example. Visualization was accomplished with DIAMOND 3.2. The analysis is of the cation of the metal complex having the structural formula VII, i.e. [iridium(3-fluorophenylpyridinato)2(6-phenyl-2,2′-bipyridine)]. Thus, the monovalent anion A⁻ is not shown. The crystal structure of the metal complex of the structural formula VII shows the strong fluorine-nitrogen interaction 9 of the 3-fluorophenylpyridinato ligands. For better illustration, the phenyl ring of the 6′-phenyl-2,2′-bipyridine ligand is omitted.

FIG. 3B shows the crystal structure of the cation of the metal complex of the structural formula VII. FIG. 3A differs from FIG. 3B by its perspective. The strong fluorine-nitrogen interactions (indicated by 9) of the 3-fluorophenylpyridinato ligands which are in the 3 position, i.e. orthogonal, to the carbon of the B2 ligand are shown. This carbon forms a coordinate bond with the transition metal M. The octahedral coordination sphere of the iridium ion is only slightly distorted. For better illustration, the phenyl ring of the 6′-phenyl-2,2′-bipyridine ligand has been omitted.

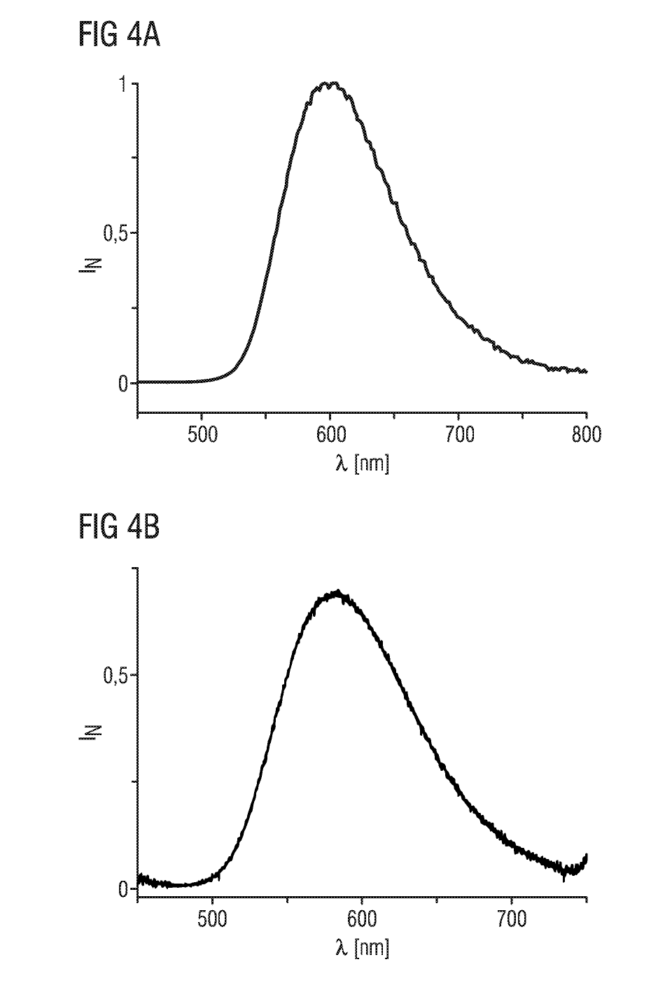

FIGS. 4A and 4B each show an emission spectrum of one embodiment. FIGS. 4A and 4B each show the metal complex of the structural formula XIII, i.e. [iridium(3-fluorophenylpyridinato)2(bathophenanthroline)]PF₆. What is shown in each case is the normalized intensity I_{N} as a function of the wavelength λ in nm. The emission spectrum of FIG. 4A shows the metal complex as a powder sample. This powder sample was excited at a wavelength of 360 nm. The metal complex shows an emission maximum at about 597 nm. FIG. 4B shows the emission spectrum of a thin-film sample which has been excited at 380 nm. The emission maximum of FIG. 4B is about 580 nm.

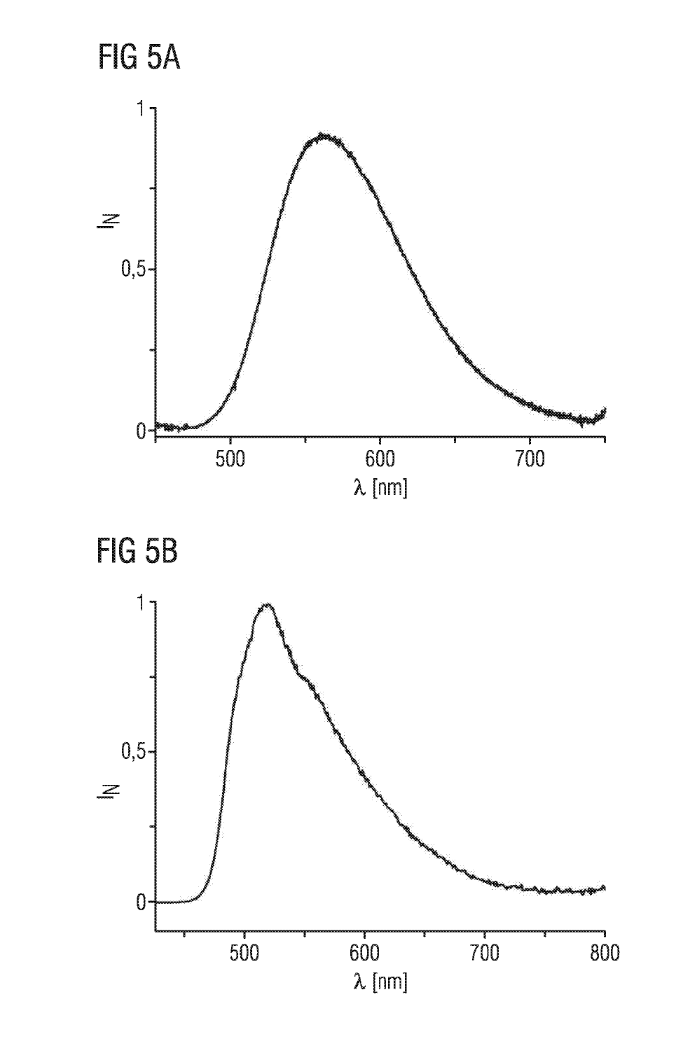

FIGS. 5A and 5B each show an emission spectrum of one embodiment, i.e. of the metal complex of the structural formula XII, i.e. [iridium(3-fluorophenylpyridinato)2(phenanthroline)]PF₆. What is shown is the normalized intensity I_{N} as a function of the wavelength λ in nm. FIG. 5A shows the emission spectrum as a thin film which has been excited at a wavelength of 380 nm. The emission maximum is about 563 nm. FIG. 5B shows the corresponding powder sample which has been excited at 360 nm. The emission maximum is about 520 nm.

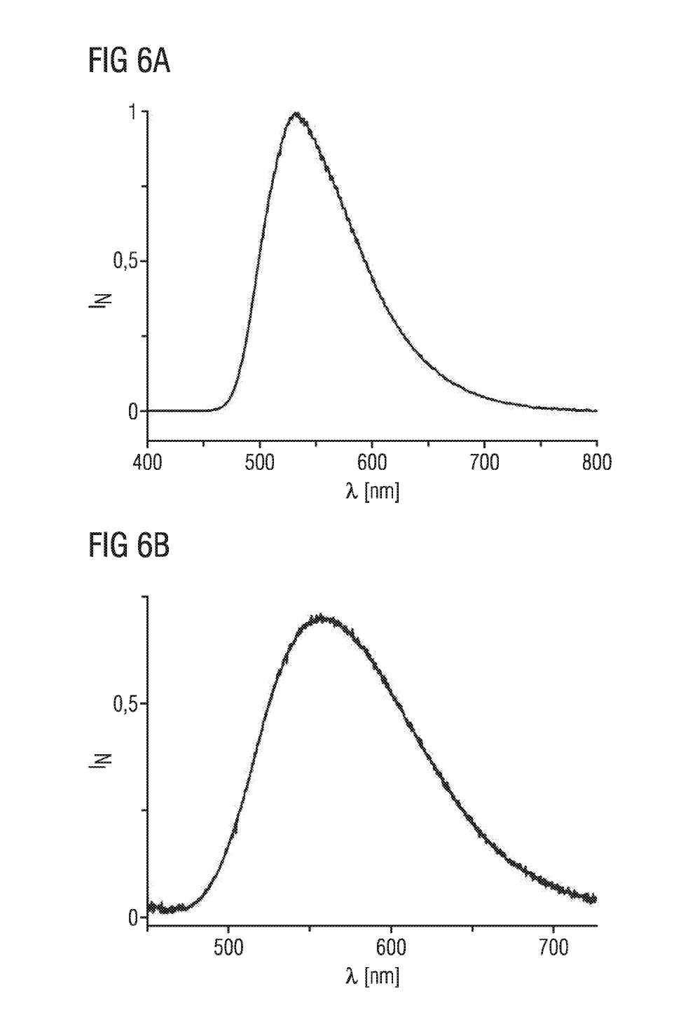

FIGS. 6A and 6B each show an emission spectrum of one embodiment, the metal complex of the structural formula VI, i.e. [iridium(3-fluorophenylpyridinato)2(4,4′-di-tert-butyl-2,2′-bipyridine)]PF₆. What is shown in each case is the normalized intensity I_{N} as a function of the wavelength λ in nm. FIG. 6A shows the spectrum of the metal complex as a powder which has been excited at 360 nm. It shows an emission maximum at about 532 nm. FIG. 6B shows the corresponding sample as a thin film which has been excited at 380 nm. The sample shows an emission maximum at about 556 nm.

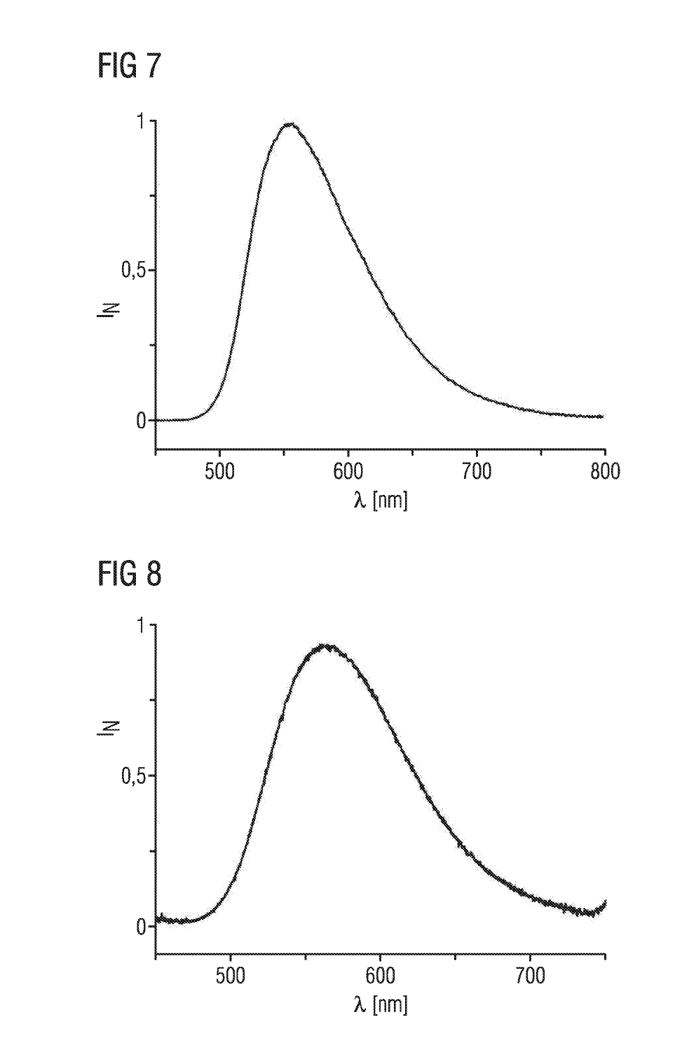

FIG. 7 shows an emission spectrum of one embodiment, the metal complex of the structural formula VII, i.e. [iridium(3-fluorophenylpyridinato)2(6-phenyl-2,2′-bipyridine)]PF₆. What is shown is the normalized intensity I_{N} as a function of the wavelength λ in nm. The sample is a powder sample and was excited at 360 nm. The sample shows an emission maximum at about 554 nm.

FIG. 8 shows an emission spectrum of one embodiment, the metal complex of the structural formula V, i.e. [iridium(3-fluorophenylpyridinato)2(2,2′-bipyridine)]PF₆. What is shown is the normalized intensity I_{N} as a function of the wavelength λ in nm. The sample was analyzed as a thin film sample with excitation at about 380 nm. The sample shows an emission maximum at about 564 nm.

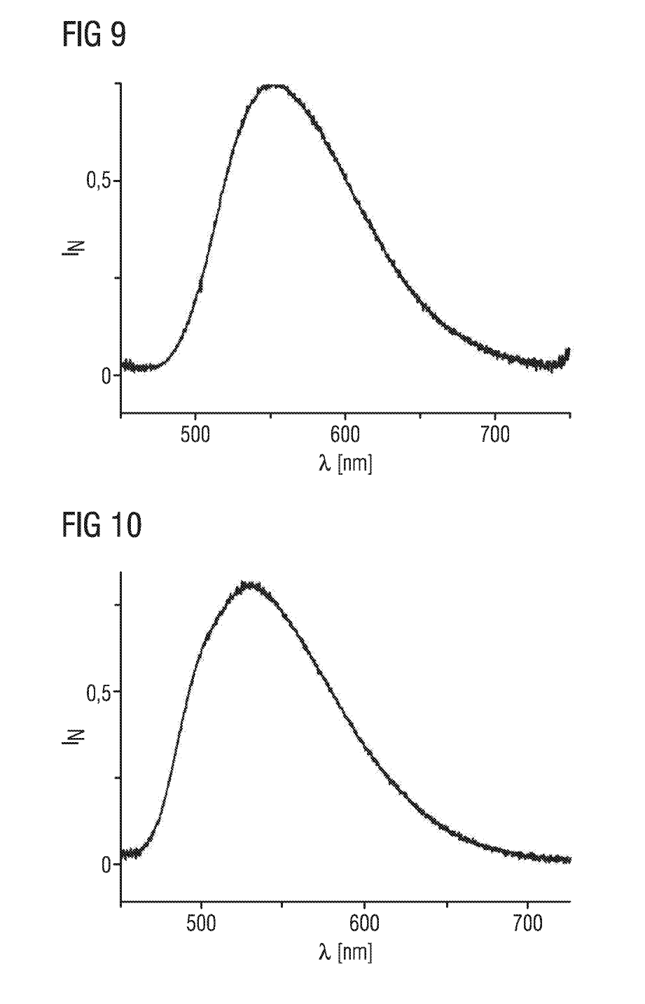

FIG. 9 shows an emission spectrum of one embodiment, the metal complex of the structural formula XIV, i.e. [iridium(3-fluorophenylpyridinato)2(bathocuproin)]PF₆. What is shown is the normalized intensity I_{N} as a function of the wavelength λ in nm.

It is a thin film sample which has been analyzed with excitation at 380 nm. The emission maximum is about 551 nm.

FIG. 10 shows an emission spectrum of one embodiment, the metal complex of the structural formula XXII, i.e. [iridium(3-fluorophenylpyridinato)2(5,5′-dimethyl-2,2′-bipyridine)]PF₆. What is shown is the normalized intensity I_{N} as a function of the wavelength λ in nm. The sample is a thin film sample and was excited at 380 nm. The sample shows an emission maximum at about 530 nm.

It is apparent from FIGS. 4A to 10 that the metal complexes of the invention shown here have emission in the green to yellow spectral region. More particularly, excitation is effected in the UV region.

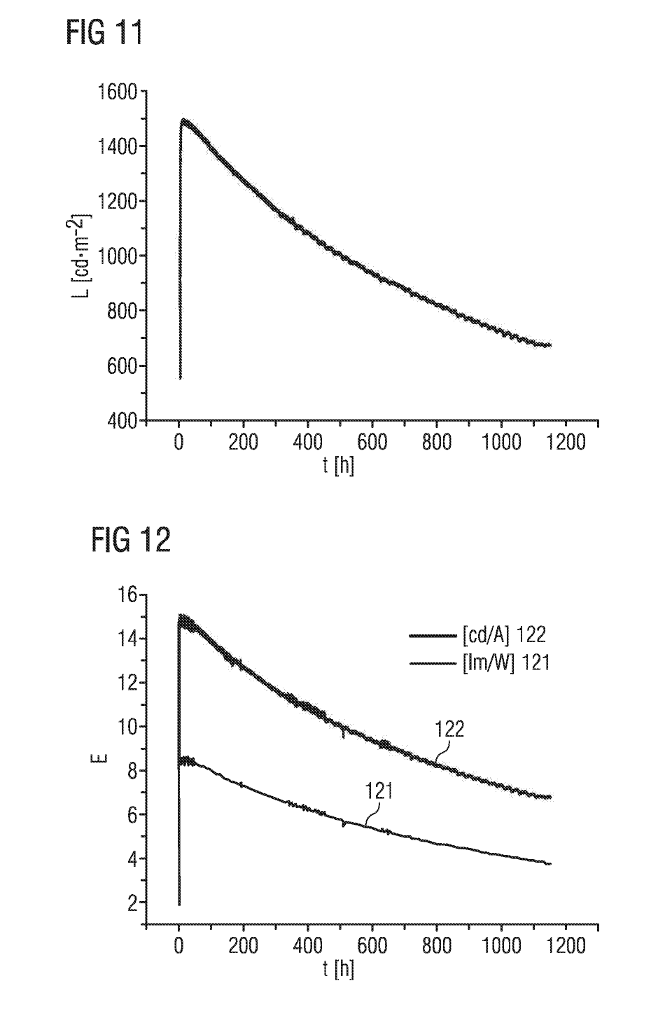

FIG. 11 shows a luminescence spectrum of one embodiment, the metal complex [iridium(3-fluorophenylpyridinato)2(2,2′-bipyridine)]PF₆. A current intensity per unit area of 100 A/m² with a duty cycle of 50% was used. The luminescence L in candelas per square meter (cd/m²) is shown as a function of time t in hours (h). It is apparent from the graph that the initial luminance has a value of about 1500 cd/m². This luminescence decreases with time and has a luminescence of 750 cd/m² after about 1000 hours.

FIG. 12 shows an efficiency spectrum of one embodiment, the metal complex [iridium(3-fluorophenylpyridinato)2(2,2′-bipyridine)]PF₆. A current intensity per unit area of 100 A/m² at a duty cycle of 50% was used. What is shown is the efficiency E as a function of time t in hours (h). The curve 121 shows the light yield in lumens per watt (lm/W). The curve 122 shows the power efficiency in candelas per ampere (cd/A). It is apparent from the power efficiency curve that still more than 50% of the power efficiency is present after about 1000 hours, compared to t=0. The light yield has a value of about 5 lm/W after 1000 hours and hence still has 62.5% of the original light yield (at t=0).

The working examples described in conjunction with the figures and the features thereof may also be combined with one another in further working examples, even when such combinations are not shown explicitly in the figures. In addition, the working examples described in conjunction with the figures may have additional or alternative features according to the description in the general part.

The invention is not restricted to the working examples by their citation in the description. Instead, the invention encompasses every novel feature and every combination of features, especially including every combination of features in the claims, even when this feature or this combination itself is not specified explicitly in the claims or working examples.

1-16. (canceled)

17. A metal complex having the structural formula I: 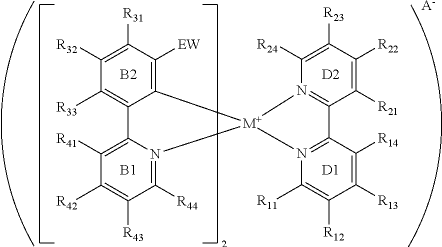
where:
M is a transition metal having an atomic number greater than 40,
a B2 ring is at least one of an aromatic or a heteroaromatic,
a B1 ring, a D1 ring and a D2 ring are each at least one nitrogen-containing ring,
A⁻ is a monovalent anion,
EW is at least one electron-withdrawing substituent, R₁₁, R₁₂, R₁₃, R₁₄, R₂₁, R₂₂, R₂₃, R₂₄, R₄₁, R₄₂, R₄₃, R₄₄ are each independently selected from the group consisting of —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀,
R₃₁, R₃₂, R₃₃ are each independently a further electron-withdrawing substituent or are each independently selected from the group consisting of —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀,
wherein R₅₀, R₆₀, R₇₀, R₈₀, R₉₀, R₁₀₀, R₁₁₀, R₂₀₀, R₂₁₀, R₂₂₀, R₂₃₀ are each independently selected from the group consisting of unbranched saturated hydrocarbon chains having 1 to 20 carbon atoms, branched saturated hydrocarbon chains having 1 to 20 carbon atoms, unbranched unsaturated hydrocarbon chains having 1 to 20 carbon atoms, branched unsaturated hydrocarbon chains having one to 20 carbon atoms, aromatic rings, nonaromatic rings, —H, —I, —Cl, —Br, —F, N+R₁₂₀R₁₃₀R₁₄₀, —SO₃R₁₅₀, —CN, —COCl, —COOR₁₆₀, —CR₁₇₀R₁₈₀OH, —CR₁₉₀O, —COH and —CHO, and
wherein R₁₂₀, R₁₃₀, R₁₄₀, R₁₅₀, R₁₆₀, R₁₇₀, R₁₈₀, R₁₉₀ are each independently selected from the group consisting of unbranched saturated hydrocarbon chains having 1 to 20 carbon atoms, branched saturated hydrocarbon chains having 1 to 20 carbon atoms and cyclic rings having 3 to 20 carbon atoms.

18. The metal complex according to claim 17, wherein the metal complex is configured to emit radiation from a green spectral region to a yellow spectral region.

19. The metal complex according claim 17, wherein EW is fluorine.

20. The metal complex according to claim 19, wherein R₃₁ and/or R₃₂ is fluorine.

21. The metal complex according to claim 17, wherein M is selected from the group consisting of Ir, Ru, Os and Pt.

22. The metal complex according to claim 17, wherein the metal complex has the following structural formula II: 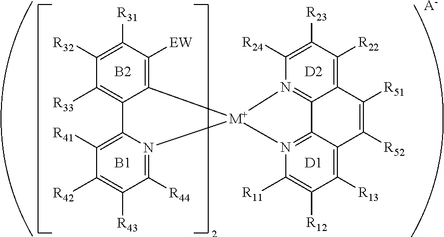
where M, the B2 ring, the B1 ring, the D1 ring, the D2 ring, A⁻, R₁₁, R₁₂, R₁₃, R₂₂, R₂₃, R₂₄, R₄₁, R₄₂, R₄₃, R₄₄, R₃₁, R₃₂ and R₃₃ are each as defined in claim 1,
wherein EW is fluorine, and
wherein R₅₁ and R₅₂ are each independently selected from the group consisting of —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀.

23. The metal complex according to claim 22, wherein EW and R₃₂ or EW and R₃₁ are each fluorine.

24. The metal complex according to claim 22, wherein R₁₃ and R₂₂ are the same and are each phenyl, tert-butyl, methyl, methoxy or hydrogen.

25. The metal complex according to claim 22, wherein R₁₁ and/or R₂₄ are each methyl.

26. An organic light-emitting component comprising:
at least one organic light-emitting layer between two electrodes,
wherein the organic light-emitting layer comprises the metal complex according to claim 17 as an emitter material.

27. The organic light-emitting component according to claim 26, wherein the organic light-emitting component is an organic light-emitting diode.

28. The organic light-emitting component according to claim 26, wherein the organic light-emitting component is an organic light-emitting electrochemical cell.

29. The organic light-emitting component according to claim 26, wherein the metal complex is distributed homogeneously in a matrix material.

30. The organic light-emitting component according to claim 26, wherein the organic light-emitting component is configured to emit radiation from a green spectral region to a yellow spectral region.

31. The organic light-emitting component according to claim 26, wherein the organic light-emitting layer is produced from a liquid phase.

32. A metal complex having the structural formula I: 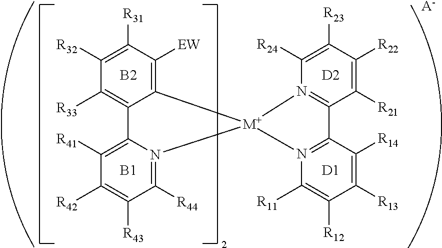
where:
the metal complex is configured to emit radiation from a green spectral region to a yellow spectral region,
M is a transition metal having an atomic number greater than 40,
a B2 ring is at least one of an aromatic or a heteroaromatic,
a B1 ring, a D1 ring and a D2 ring are each at least one nitrogen-containing ring, the B1 ring is an uncondensed pyridine,
A⁻ is a monovalent anion,
EW is at least one electron-withdrawing substituent, R₁₁, R₁₂, R₁₃, R₁₄, R₂₁, R₂₂, R₂₃, R₂₄, R₄₁, R₄₂, R₄₃, R₄₄ are each independently selected from the group consisting of —H, —OH, —R₅₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀,
R₃₁, R₃₂, R₃₃ are each independently a further electron-withdrawing substituent or are each independently selected from the group consisting of —H, —OH, —R₅₀₀, -phenyl, —OCOR₆₀, —NHCOR₇₀, —OR₈₀, —NR₉₀R₁₀₀, —NHR₁₁₀, —NH₂, —C═, —C═C, —C═C—, —C, —F, —Cl, —Br, —I, —CN, —NO₂, —COCl, —COOH, —SO₃R₂₀₀, —CHO and —N⁺R₂₁₀R₂₂₀R₂₃₀,
wherein R₅₀, R₆₀, R₇₀, R₈₀, R₉₀, R₁₀₀, R₁₁₀, R₂₀₀, R₂₁₀, R₂₂₀, R₂₃₀ are each independently selected from the group consisting of unbranched saturated hydrocarbon chains having 1 to 20 carbon atoms, branched saturated hydrocarbon chains having 1 to 20 carbon atoms, unbranched unsaturated hydrocarbon chains having 1 to 20 carbon atoms, branched unsaturated hydrocarbon chains having 1 to 20 carbon atoms, aromatic rings, nonaromatic rings, —H, —I, —Cl, —Br, —F, N+R₁₂₀R₁₃₀R₁₄₀, —SO₃R₁₅₀, —CN, —COCl, —COOR₁₆₀, —CR₁₇₀R₁₈₀OH, —CR₁₉₀O, —COH and —CHO, and
wherein R₁₂₀, R₁₃₀, R₁₄₀, R₁₅₀, R₁₆₀, R₁₇₀, R₁₈₀, R₁₉₀ are each independently selected from the group consisting of unbranched saturated hydrocarbon chains having 1 to 20 carbon atoms, branched saturated hydrocarbon chains having 1 to 20 carbon atoms and cyclic rings having 3 to 20 carbon atoms.
